(19) United States
(12) Patent Application Publication
(10) Pub. No.: US 2009/0108926 A1
(43) Pub. Date: Apr. 30, 2009

(54) FILTER CIRCUIT

(75) Inventor: Isao Tsuyama, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/259,119

(22) Filed: Oct. 27, 2008

(30) Foreign Application Priority Data
Oct. 29, 2007 (JP) 2007-280245

(51) Int. Cl. H03K 5/00

(52) U.S. Cl. 327/552

(57) ABSTRACT

One aspect of the embodiments utilizes a filter circuit which can be connected to a signal source has a low-frequency cutoff of 1/(R×C). The filter includes a buffer circuit which can be connected to an output end of the signal source and has an output impedance of R, and a capacitor which is connected to an output end of the buffer circuit in a floating state and has a capacitance of C/2. The filter includes a resistor circuit which is connected to an output end of the capacitor and has a resistance value of R.

### CROSS-REFERENCE TO RELATED APPLICATION

This application is based upon and claims the better of priority of prior Japanese Patent Application No. 2007-280245, filed on Oct. 29, 2007, the entire contents of which are incorporated herein by reference.

### BACKGROUND

1. Field

The present technique relates to a filter circuit which can be connected to a signal source and has a low-frequency cutoff.

2. Description of the Related Art

A high-frequency emphasis circuit is used as an amplitude equalizer which compensates for signal deterioration at high frequencies in the transmission of high frequency signals. The signal deterioration is caused by a bandwidth shortage on a transmission line.

Prior art techniques relating to the present technique include a filter circuit which can set frequency characteristics according to a voltage-current conversion factor (for example, see Japanese Patent No. 2,507,010).

However, in the above amplitude equalizer, circuit element values (capacitor C, resistor R, and so on) decrease with frequencies to be equalized. In this case, an input signal source cannot be regarded as an ideal voltage source and the influence of a signal source impedance causes a deviation from the original design value (a value determined by the circuit element values).

For example, when a capacitor C in an analog filter circuit and the like is used in a floating state and when an impedance on the secondary side of the capacitor C is not so large, it is necessary to consider the influence of the output impedance of a driving voltage source fundamentally disposed on a ground point.

As a specific example, the following will examine a high-pass circuit having a capacitor C and a voltage-current conversion circuit Gm. The capacitor C has a capacitance of C. The voltage-current conversion circuit Gm has a gain value of Gm. The capacitor C is connected in series with an input signal source and is used in a floating state. On the output end of the capacitor C, the voltage-current conversion circuit Gm provided with a negative feedback is used instead of a resistor R. The resistor R has a resistance value of R(=1/Gm). Assuming that the signal source is an ideal voltage source, each low-frequency cutoff is given by Gm/C.

When a handled signal has a low frequency, the impedance of the signal source is sufficiently lower than a selectable 1/Gm value and thus is negligible. However, as the frequency increases, the 1/Gm value inevitably decreases and the impedance of the signal source cannot be ignored. For example, when the signal source has an impedance of Zi, the value of C is regarded as a value (1+Gm*Zi) times as large as the value of C in a strict sense, so that the cutoff frequency supposed to be Gm/C as a design value is shifted to a lower frequency.

Similarly, a gain is attenuated below the original value by the influence of the signal source impedance. Because of a difference between the design value and an actual value, required characteristics may not be obtained, which is an undesirable state.

The following will describe an example of a high pass filter (HPF) in a high-frequency emphasis circuit. FIG. 45 is a circuit diagram illustrating an example of a configuration of a HPF according to the prior art. The HPF includes a signal source 1 which is a K amplifier, a capacitor 3, and a resistor circuit 2. The capacitor 3 is connected to the output end of the signal source 1 and has a capacitance of C. The resistor circuit 2 is connected to the output end of the capacitor C. Ri represents an output impedance of the K amplifier. The resistor circuit 2 is realized by a voltage-current conversion circuit (a transconductance amplifier, a Gm circuit) having a negative feedback output. The voltage-current conversion circuit has a conductance of Gm2 and the resistor circuit 2 has a resistance value of R=1/Gm2.

The following will analyze how the transfer function of the HPF is changed by the presence of Ri.

The relational expression of FIG. 46 is established by Kirchhoff's second law (Kirchhoff's voltage law).

Thus the HPF has a transfer function expressed in FIG. 47. As is evident from this expression, a desired gain of one is compressed (attenuated) by 1/(1+Gm2·Ri) by the presence of the signal source resistance Ri and conversely, C is multiplied by (1+Gm2·Ri). In other words, the cutoff frequency falls below the original design value. This is because Ri in the signal source 1 divides a voltage between the signal source 1 and the resistor circuit 2 and attenuates a signal, and simultaneously, Ri acts as a load impedance to the resistor circuit 2 and causes a gain, resulting in a mirror effect.

FIG. 48 is a graph showing the influence of Ri. In FIG. 48, the horizontal axis represents an angular frequency ω and the vertical axis represents a gain of the K amplifier. It is considered that an Ri sufficiently small relative to 1/Gm2 does not seriously affect the gain, but the influence of Ri cannot be ignored when Gm2 decreases for use at high frequencies.

In the case where the influence of such a signal source impedance is eliminated in the prior art, efforts are made to minimize a target output impedance by providing a buffer circuit and the like. However, a reduction in output impedance involves advanced circuit technology and higher power consumption. Thus circuit design becomes more difficult for higher frequencies. Further, it is practically impossible to realize an ideal voltage source and reduction in output impedance has reached its limit.

An object of the present technique is to provide a filter circuit which can reduce the influence of a signal source impedance.

### SUMMARY

In keeping with one aspect of an embodiment of this technique, a filter circuit which can be connected to a signal source has a low-frequency cutoff of 1/(R×C). The filter circuit includes a buffer circuit which can be connected to an output end of the signal source and has an output impedance of R, and a capacitor which is connected to an output end of the buffer circuit in a floating state and has a capacitance of C/2. The filter includes a resistor circuit which is connected to an output end of the capacitor and has a resistance value of R.

Additional objects and advantages of the embodiment will be set forth in part in the description which follows, and in part will be obvious from the description, or may be learned by practice of the embodiment. The object and advantages of the embodiment will be realized and attained by means of the elements and combinations particularly pointed out in the appended claims.

It is to be understood that both the foregoing general description and the following detailed are exemplary and explanatory only and are not restrictive of the embodiment, as claimed.

### BRIEF DESCRIPTION OF THE DRAWINGS

FIG. 1 shows an example of the transfer function of a single-end HPF;

FIG. 2 shows an expression representing an example of the transfer function of the HPF according to a first embodiment;

FIG. 3 is a circuit diagram of an equivalent circuit illustrating an example of the configuration of the HPF according to the first embodiment;

FIG. 4 is a circuit diagram showing an example of the configuration of the HPF according to the first embodiment;

FIG. 5 is a circuit diagram of an equivalent circuit illustrating an example of the configuration of an HPF according to a comparative example for a comparative calculation;

FIG. 6 shows an expression representing a calculation model of the HPF according to the comparative example;

FIG. 7 is a circuit diagram of an equivalent circuit illustrating an example of the configuration of the HPF according to the first embodiment for a comparative calculation;

FIG. 8 shows an expression of Gm2A according to the first embodiment;

FIG. 9 shows an expression of Gm1 according to the first embodiment;

FIG. 10 shows an expression representing a calculation model of the HPF according to the first embodiment;

FIG. 11 is a table showing the calculation conditions of the comparative calculations on the comparative example and the first embodiment;

FIG. 12 is a graph showing the characteristics of fc relative to Gm in the case of Ri=5Ω;

FIG. 13 is a graph showing deviations from the theoretical value of fc in the case of Ri=5Ω;

FIG. 14 is a graph showing deviations from the theoretical value of a gain in the case of Ri=5Ω;

FIG. 15 is a graph showing the characteristics of fc relative to Gm in the case of Ri=10Ω;

FIG. 16 is a graph showing deviations from the theoretical value of fc in the case of Ri=10Ω;

FIG. 17 is a graph showing deviations from the theoretical value of a gain in the case of Ri=10Ω;

FIG. 18 is a graph showing the characteristics of fc relative to Gm in the case of Ri=20Ω;

FIG. 19 is a graph showing deviations from the theoretical value of fc in the case of Ri=20Ω;

FIG. 20 is a graph showing deviations from the theoretical value of a gain in the case of Ri=20Ω;

FIG. 21 is a circuit diagram showing an example of the configuration of an HPF according to a second embodiment;

FIG. 22 shows a relational expression established regarding a current charged to C/2 according to the second embodiment;

FIG. 23 shows a relational expression established by Kirchhoff's first law according to the second embodiment;

FIG. 24 shows an expression representing a transfer function of an HPF stage according to the second embodiment;

FIG. 25 shows an expression representing the conditions of Gm1 and Gm2 according to the second embodiment;

FIG. 26 shows an expression representing a transfer function of the HPF stage after compensation according to the second embodiment;

FIG. 27 is a circuit diagram showing an example of the configuration of a voltage-current conversion circuit having a bipolar unbalanced differential pair;

FIG. 28 is a circuit diagram showing an example of the configuration of a voltage-current conversion circuit having a CMOS unbalanced differential pair;

FIG. 29 is a circuit diagram showing an example of the configuration of a voltage-current conversion circuit having a CMOS linear resistor;

FIG. 30 shows an expression representing a transfer function of a bilinear equalizer;

FIG. 31 is a circuit diagram showing an example of the configuration of the bilinear equalizer;

FIG. 32 shows a relational expression established regarding a current charged to C in the bilinear equalizer;

FIG. 33 is a relational expression derived from the expression of FIG. 32 regarding Vout and Vin;

FIG. 34 shows an expression representing a transfer function of a Gm-C circuit of the bilinear equalizer;

FIG. 35 is a circuit diagram showing an example of the Gm stage of dual-input type sharing a common-mode feedback loop;

FIG. 36 is a circuit diagram of an equivalent circuit illustrating an example of the configuration of a bilinear equalizer in consideration of an output impedance Ri;

FIG. 37 shows a relational expression representing an output Vout of the bilinear equalizer in consideration of Ri;

FIG. 38 shows an expression representing a transfer function of the bilinear equalizer in consideration of Ri;

FIG. 39 shows an expression representing a transfer function of the bilinear equalizer after compensation in consideration of Ri;

FIG. 40 is a circuit diagram showing an example of the configuration of a bilinear equalizer according to a third embodiment;

FIG. 41 shows a relational expression established by Kirchhoff's first law regarding a contact on the primary side of C in the bilinear equalizer according to the third embodiment;

FIG. 42 shows a relational expression representing an output Vout of the bilinear equalizer according to the third embodiment;

FIG. 43 shows an expression representing a transfer function of the bilinear equalizer according to the third embodiment;

FIG. 44 shows an expression representing a transfer function of the bilinear equalizer under certain conditions according to the third embodiment;

FIG. 45 is a circuit diagram of an equivalent circuit illustrating an example of the configuration of an HPF according to the prior art;

FIG. 46 shows a relational expression established by Kirchhoff's second law in the HPF of the prior art;

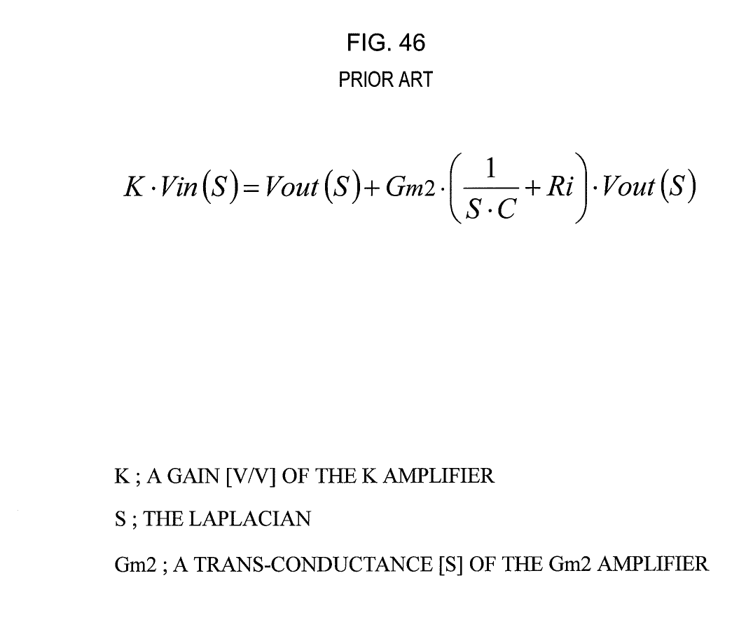

FIG. 47 shows an expression representing a transfer function of the HPF of the prior art; and

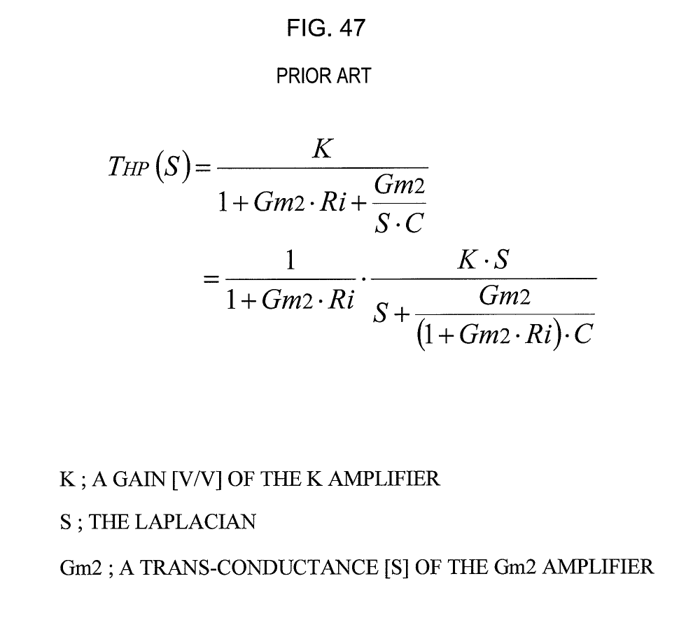

FIG. 48 is a graph showing the influence of Ri.

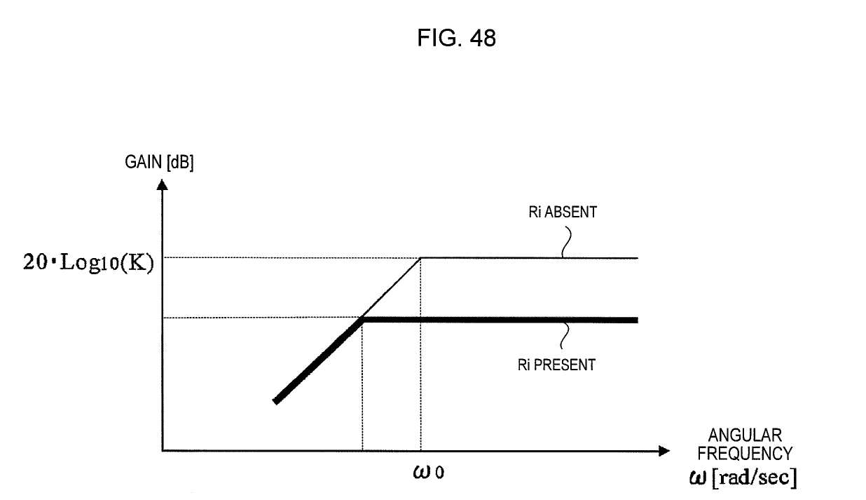

### DETAILED DESCRIPTION OF THE EMBODIMENT

Embodiments of the present technique will be described below in accordance with the accompanying drawings.

### 1. First Embodiment

The present embodiment is a single-end primary HPF (Gm-C primary HPF) using the present technique.

In the prior art, the influence of the signal source impedance Ri in the primary HPF is caused by a gain occurring between Ri and Gm.

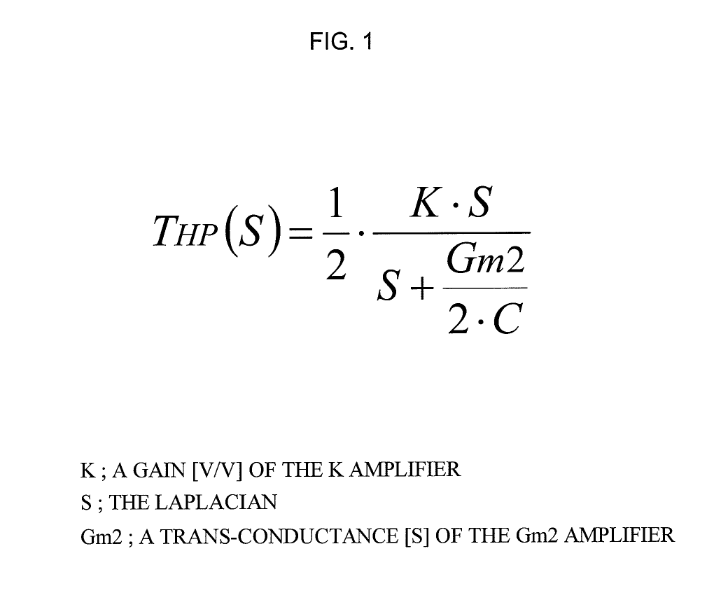

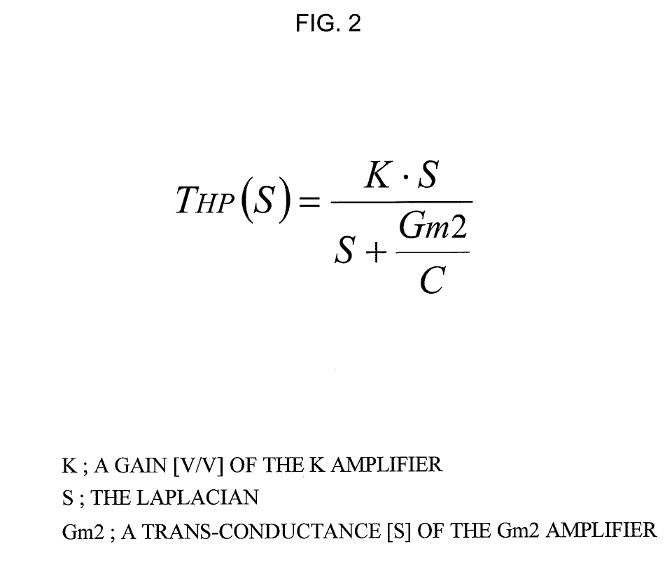

Thus in the case of Ri=1/Gm2, a transfer function THP(S) of a HPF stage is expressed as shown in FIG. 1. Further, in the case where C is set at half the original design value and compensation is performed to have a double-gain stage (an offset of a signal source impedance), the HPF stage after the compensation has a transfer function expressed in FIG. 2, which is the original HPF transfer function. In this way, a signal source resistance can be offset.

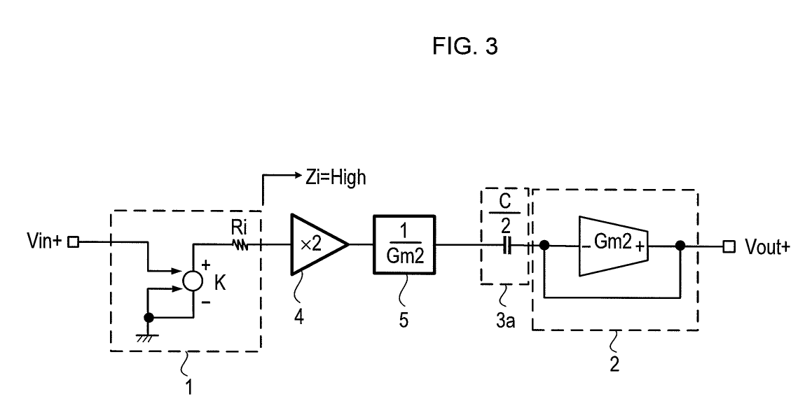

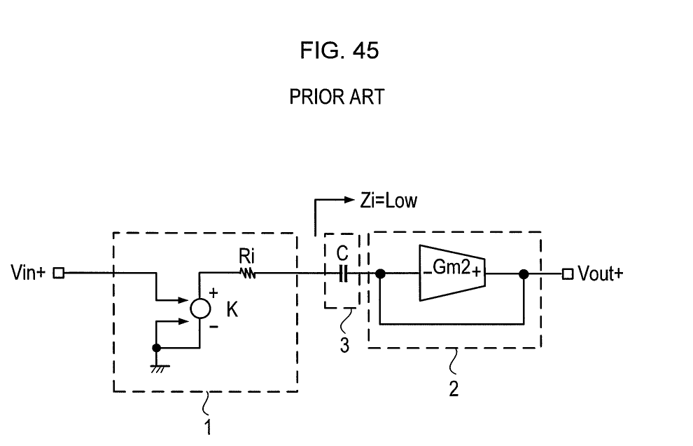

The following will describe the configuration of a single-end HPF for realizing the transfer function after the compensation. The HPF is realized as a single-end one-pole HPF using a floating C and will be described below. FIG. 3 is a circuit diagram of an equivalent circuit indicating an example of the configuration of the HPF according to a first embodiment. In FIG. 3, the same reference numerals as those of FIG. 45 denote components similar to or corresponding to the components of FIG. 45 and the explanation thereof is omitted. As compared with FIG. 45, a capacitor 3a is provided instead of the capacitor 3 and an amplifier circuit 4 and a buffer circuit 5 are further provided in FIG. 3.

The capacitor 3a has a capacitance of C/2. The buffer circuit 5 is similar to a resistor circuit 2. The buffer circuit 5 attenuates a transfer function to a half and the amplifier circuit 4 has a double gain for compensating for the transfer function.

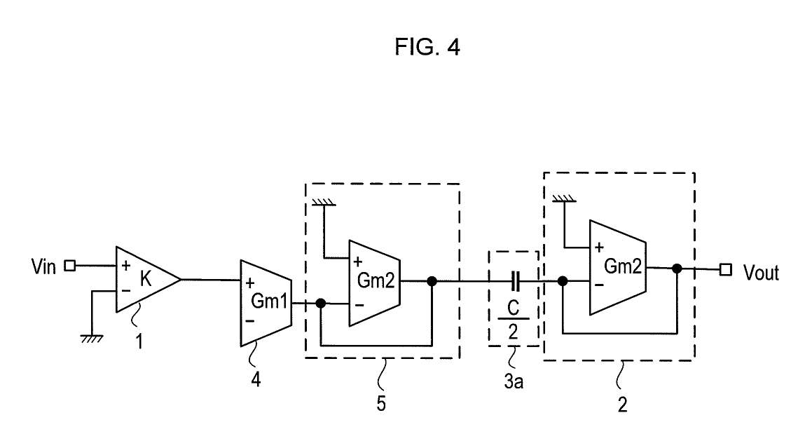

FIG. 4 is a circuit diagram showing an example of the configuration of the HPF according to the first embodiment. FIG. 4 specifically illustrates the circuit of FIG. 3. As described above, the resistor circuit 2 and the buffer circuit 5 are similar to each other. The amplifier circuit 4 has a conductance of Gm1=2*Gm1.

The following will describe the effect of the present embodiment.

Regarding an error of a low-frequency cutoff of the HPF at a target frequency and an error of a passband gain relative to a theoretical value (design value), a comparison is made between a HPF (Gm-C primary HPF) of a comparative example not using the present technique and the HPF (Gm-C primary HPF) of the first embodiment.

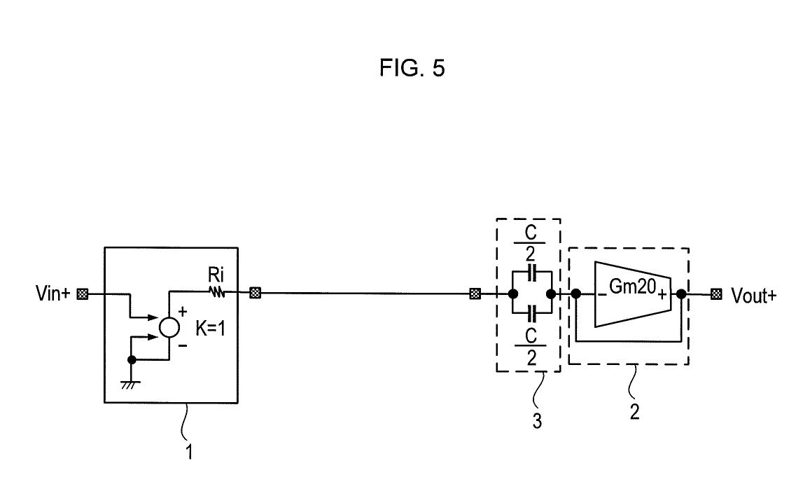

FIG. 5 is a circuit diagram of an equivalent circuit illustrating an example of the configuration of the HPF, which is the comparative example for a comparative calculation. In FIG. 5, the same reference numerals as those of FIG. 4 denote components identical to or corresponding to the components of FIG. 45. A capacitor 3 includes two capacitors each of which have a capacitance of C/2 and are connected in parallel. Further, a voltage-current conversion circuit in a resistor circuit 2 has a conductance of Gm20.

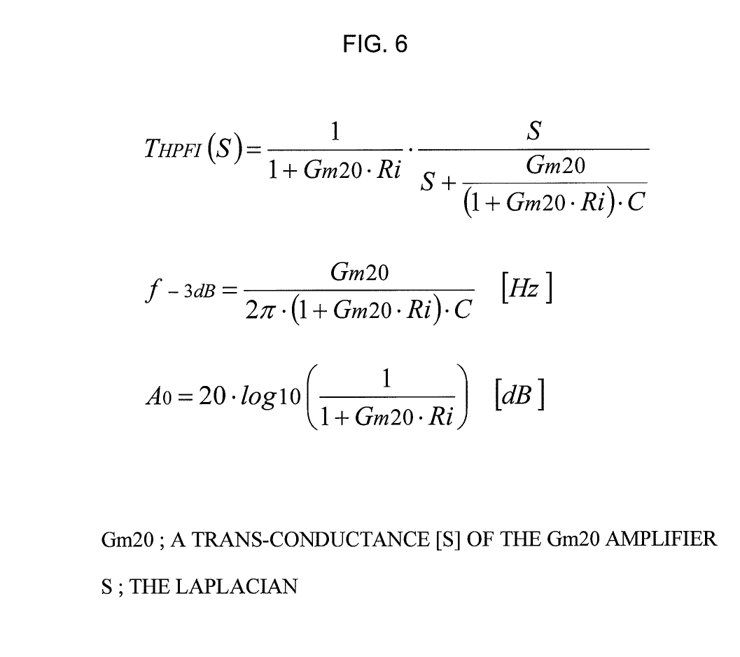

As a calculation model of the HPF of the comparative example, a transfer function THPF1(S), a cutoff frequency f-3 dB, and a passband flat gain A0 can be expressed as shown in FIG. 6.

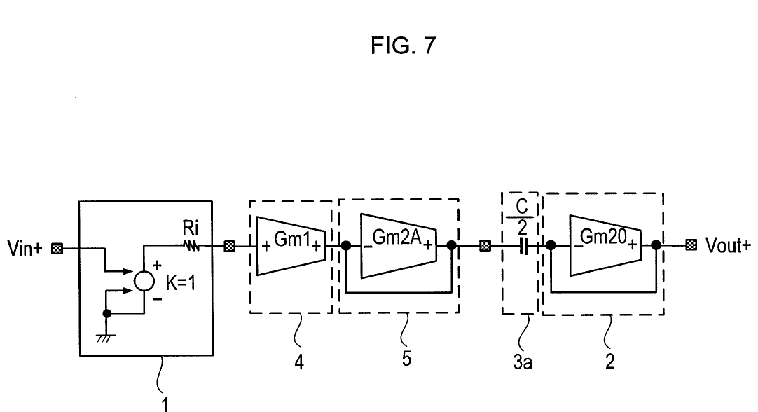

FIG. 7 is a circuit diagram of an equivalent circuit illustrating an example of the configuration of the HPF according to the first embodiment for a comparative calculation. A buffer circuit is inserted between a signal source and C. In FIG. 7, the same reference numerals as those of FIG. 2 denote members similar to or corresponding to the members of FIG. 2. A voltage-current conversion circuit in the buffer circuit 5 has a conductance of Gm2A.

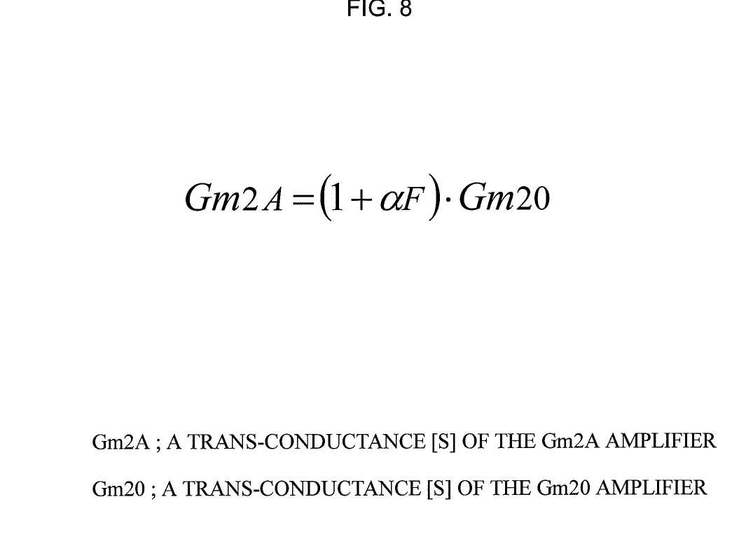

In the buffer circuit of the present embodiment, Gm1 has a sufficiently large input impedance, and thus a signal source resistance can be ignored. However, it is necessary to consider the relative variations of the Gm circuit of the buffer circuit. When Gm2A in the buffer circuit has an error of αF relative to Gm20, Gm2A can be expressed as shown in FIG. 8.

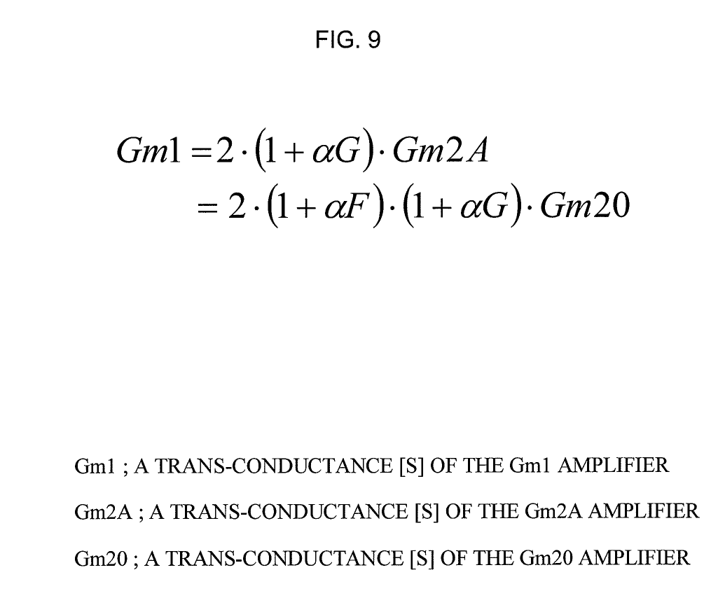

Similarly, when Gm1 in the buffer circuit has an error of αG relative to Gm2A, Gm1 can be expressed as shown in FIG. 9.

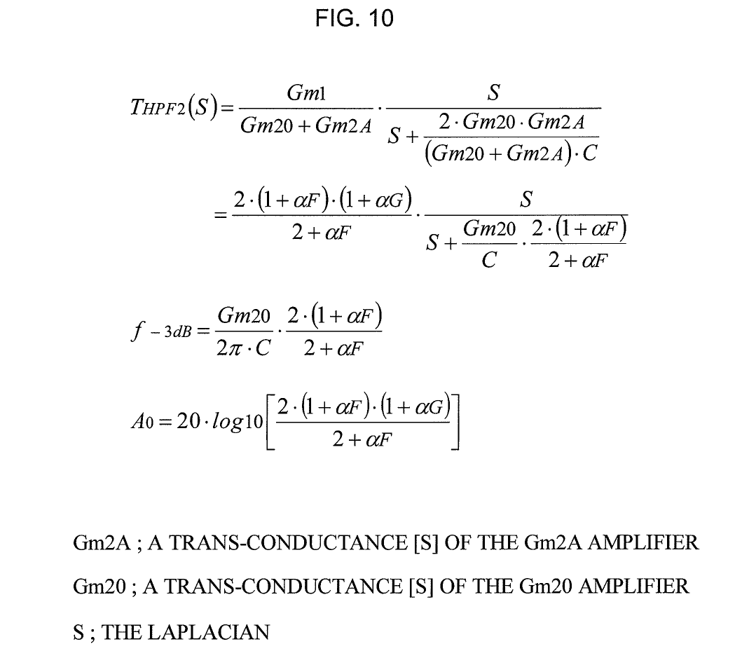

Considering these relative errors, as a calculation model of the HPF of the present embodiment, a transfer function THPF2(S), a low-frequency cutoff f-3 dB, and a passband flat gain A0 can be expressed as shown in FIG. 10.

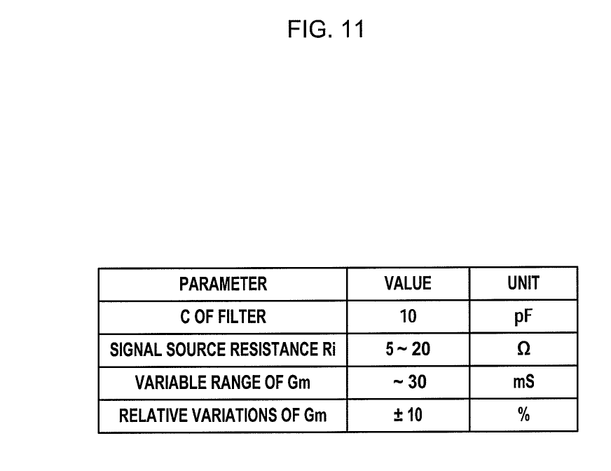

Next, comparative calculations are performed on the errors relative to the theoretical value by using the calculation models. FIG. 11 is a table showing the calculation conditions of the comparative calculations on the comparative example and the first embodiment. The table shows the conditions of the parameters of C in the HPF, the signal source resistance Ri, the variable range of Gm, and the relative variations of Gm. In this table, C is a value based on an actual value (several pFs to several tens pFs) in an LSI. Ri is an output resistance of about 30 (Ω*mA) at room temperature in the case of the emitter follower output stage of a bipolar transistor. In the case of a CMOS source follower, the Ri is a value several times as large as the output resistance. The variable range of Gm is a value corresponding to fc to 500 [MHz] in combination with C. It is considered that the relative variations of Gm are about several percents in an LSI, but in this example, it is assumed that the relative variations are somewhat large in a CMOS process.

In the HPF of the comparative example, the presence of a signal source resistance acts in a direction that reduces both the cutoff frequency and the passband gain. Thus also in the HPF of the present embodiment, the relative variations of Gm were considered for comparison only in a direction that reduces both the cutoff frequency and the passband gain. Actually, the relative variations of Gm occur both in positive and negative directions and thus cancel each other out, so that the relative variations are reduced to a certain extent. Therefore, the above calculation conditions are pertinent conditions for the HPF of the present embodiment.

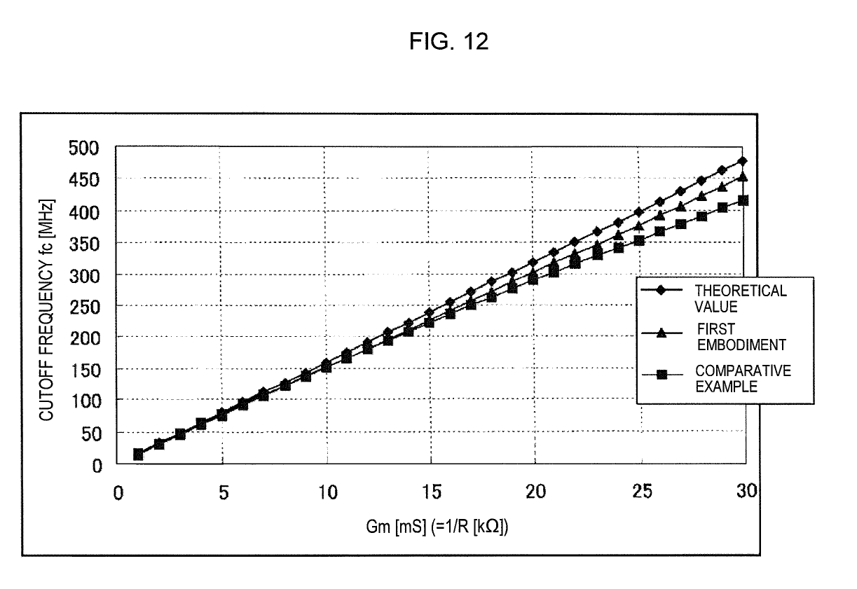

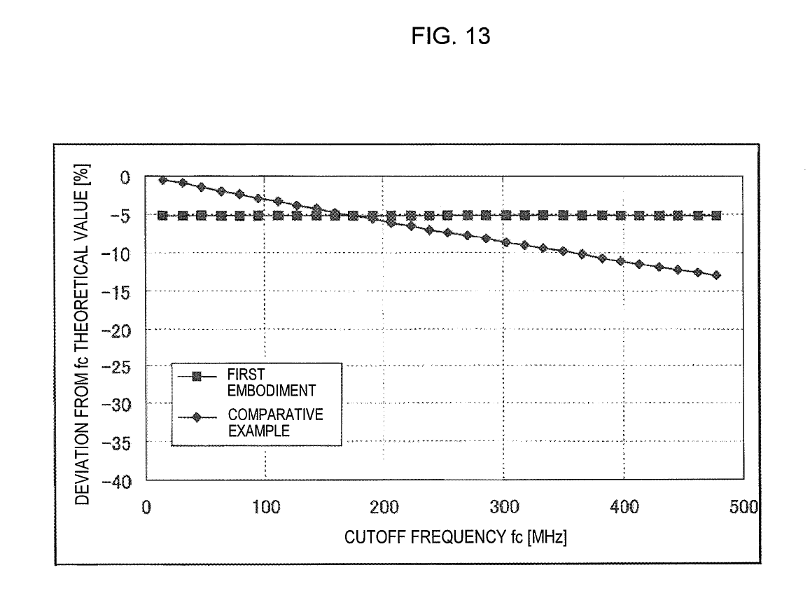

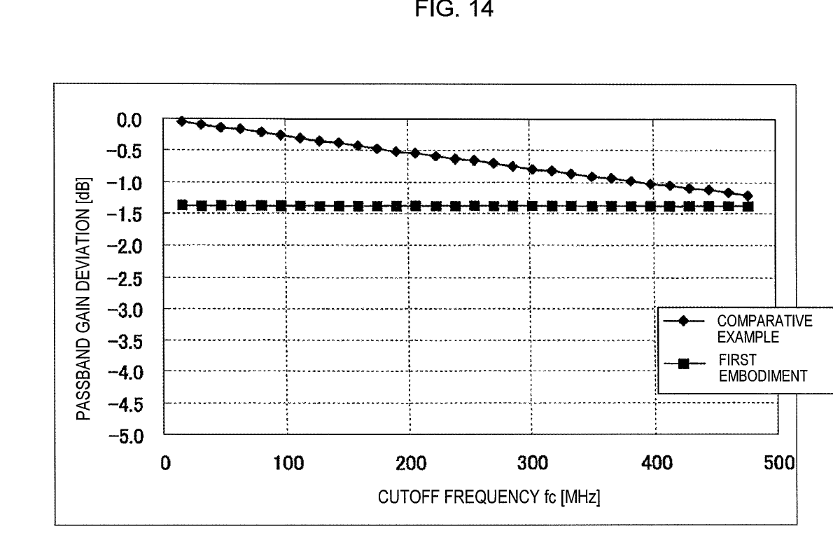

First, a comparison result of Ri=5Ω will be discussed below. FIG. 12 is a graph showing the characteristics of fc relative to Gm in the case of Ri=5Ω. FIG. 13 is a graph showing deviations from the theoretical value of fc in the case of Ri=5Ω. FIG. 14 is a graph showing deviations from the theoretical value of a gain in the case of Ri=5Ω.

In the case of Ri=5Ω, an error of the cutoff frequency in the comparative example is larger from when fc exceeds 160 MHz.

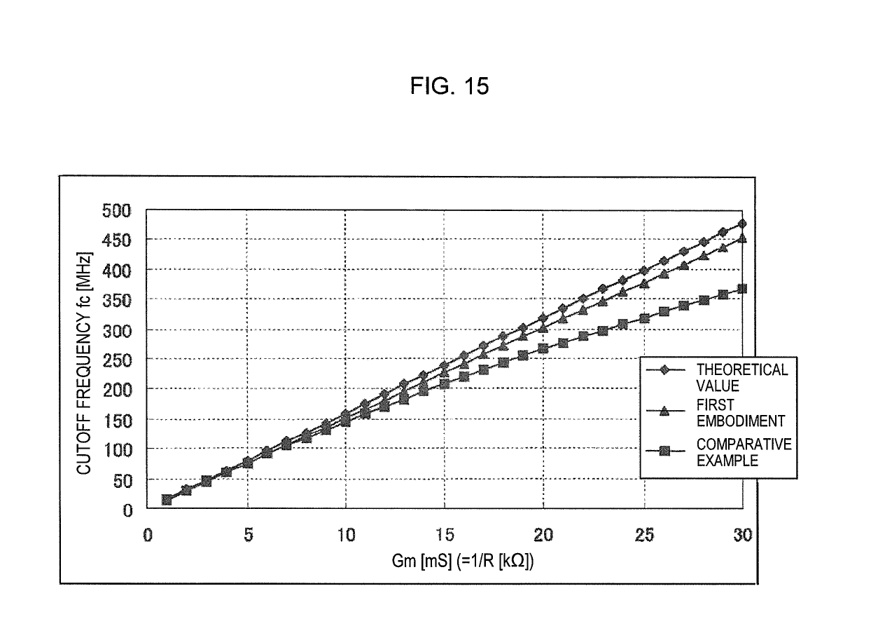

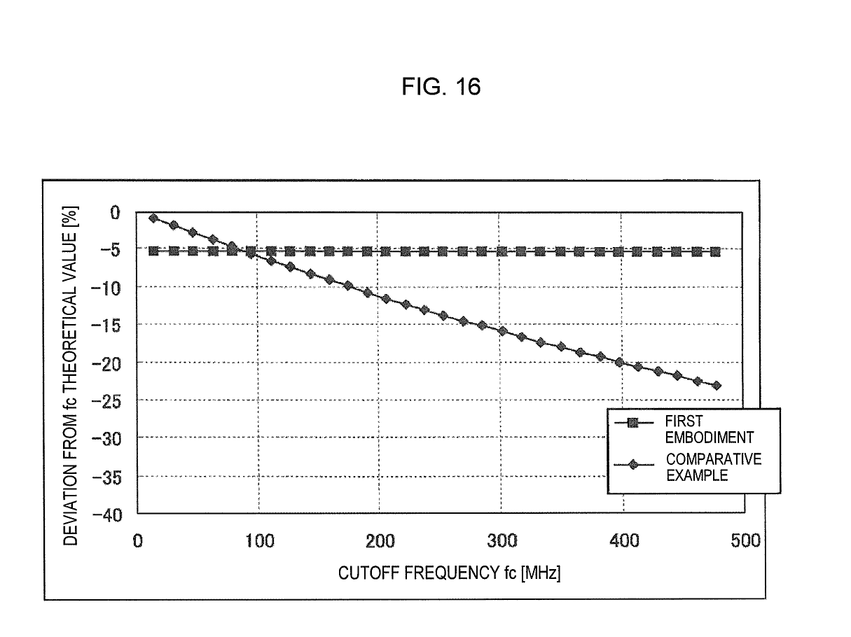

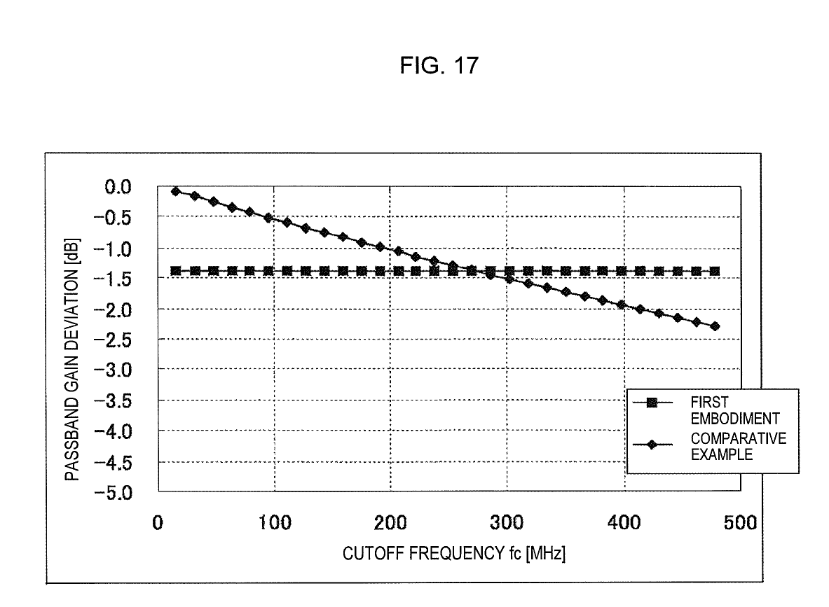

The following will discuss a comparison result of Ri=10Ω. FIG. 15 is a graph showing the characteristics of fc relative to Gm in the case of Ri=10Ω. FIG. 16 is a graph showing deviations from the theoretical value of fc in the case of Ri=10Ω. FIG. 17 is a graph showing deviations from the theoretical value of a gain in the case of Ri=10Ω.

In the case of Ri=10Ω, a frequency at which an fc error of the comparative example exceeds an fc error of the present embodiment decreases to 90 MHz. Further, around from 280 MHz, a gain error of the comparative example exceeds a gain error of the present embodiment.

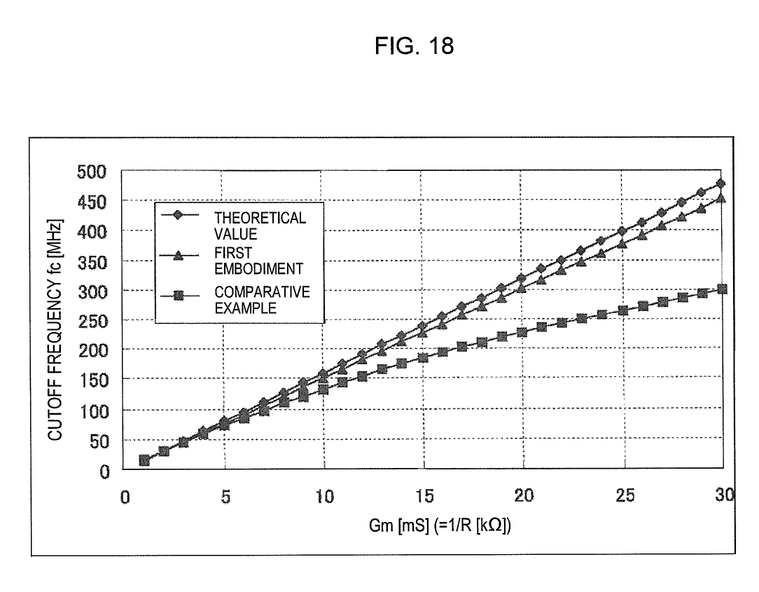

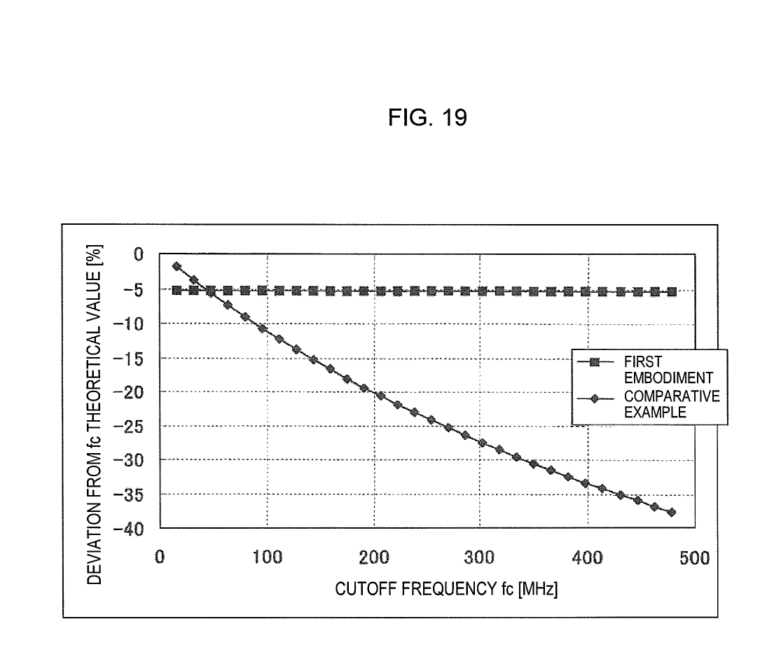

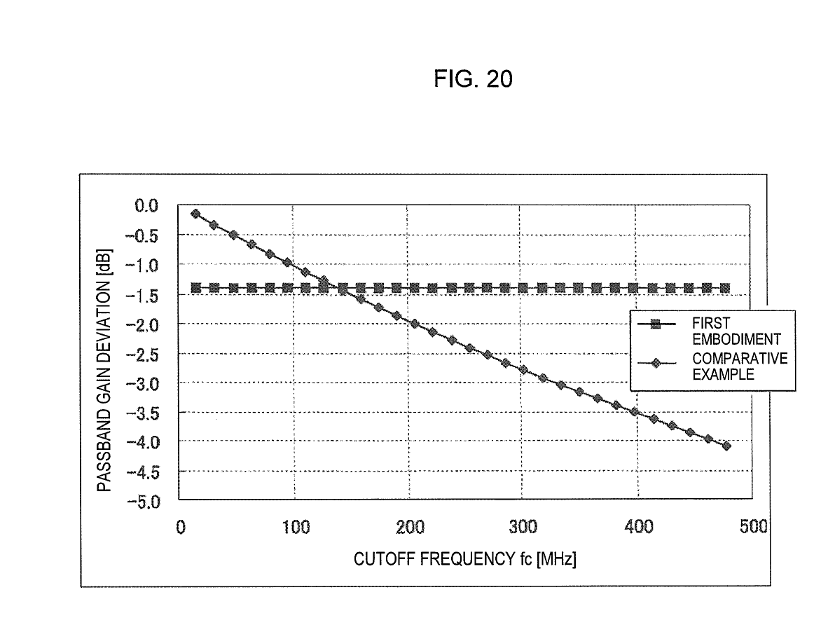

The following will discuss a comparison result of Ri=20Ω. FIG. 18 is a graph showing the characteristics of fc relative to Gm in the case of Ri=20Ω. FIG. 19 is a graph showing deviations from the theoretical value of fc in the case of Ri=20Ω. FIG. 20 is a graph showing deviations from the theoretical value of a gain in the case of Ri=20Ω.

In the case of Ri=20Ω, a frequency at which an fc error of the comparative example exceeds an fc error of the present embodiment further decreases to about 40 MHz. At a particular used frequency, the characteristics of the present embodiment are superior to those of the comparative example. Further, a frequency at which a gain error of the comparative example exceeds a gain error of the present embodiment decreases to about 140 MHz.

As described in the above comparative calculations, regarding errors from the theoretical values of a cutoff frequency and a gain, a frequency band where an error of the comparative example exceeds an error of the present embodiment expands as the signal source resistance value increases. Further, a difference between the present embodiment and the comparative example increases with the cutoff frequency. In other words, the effect of the HPF of the present embodiment is enhanced at higher frequencies.

Another feature is that an error of the HPF of the comparative example depends upon the cutoff frequency, whereas an error of the HPF of the present embodiment does not depend upon the cutoff frequency and a dominant factor of the present embodiment is the relative variations of Gm. Thus when the relative variations of an element are reduced by advanced process technology, the characteristics of the HPF can be closer to ideal characteristics.

As described above, the present embodiment can reduce the influence of a signal source impedance. Thus it is possible to reduce a difference between a theoretical value and an actual value.

### 2. Second Embodiment

The present embodiment will describe a fully differential primary HPF using the present technique. The HPF of the present embodiment is obtained by applying the compensating method of the first embodiment to a fully differential HPF.

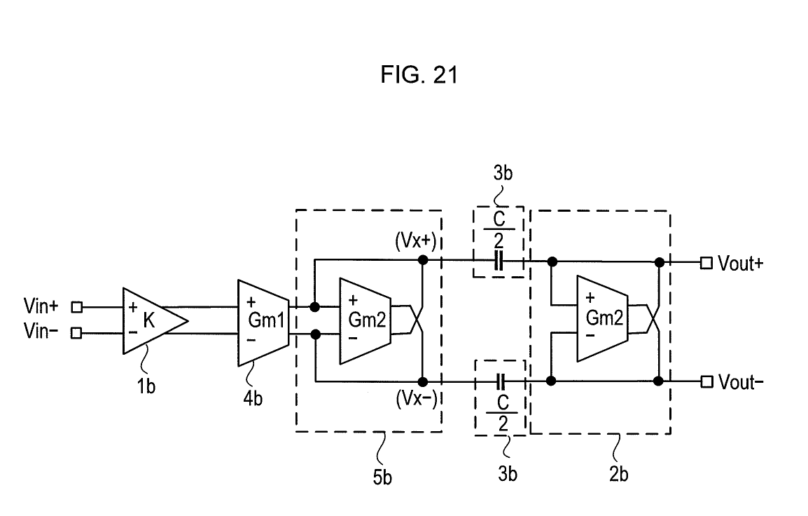

FIG. 21 is a circuit diagram showing an example of the configuration of the HPF according to a second embodiment. In FIG. 21, the same reference numerals as those of FIG. 3 denote components similar to or corresponding to the components of FIG. 3. As compared with FIG. 3, in FIG. 21, a signal source 1b having a differential configuration is provided instead of the single-end signal source 1, an amplifier circuit 4b having a differential configuration is provided instead of the single-end amplifier circuit 4, a buffer circuit 5b having a differential configuration is provided instead of the single-end buffer circuit 5, two capacitors 3b are provided instead of the capacitor 3a, and a resistor circuit 2b having a differential configuration is provided instead of the single-end resistor circuit 2.

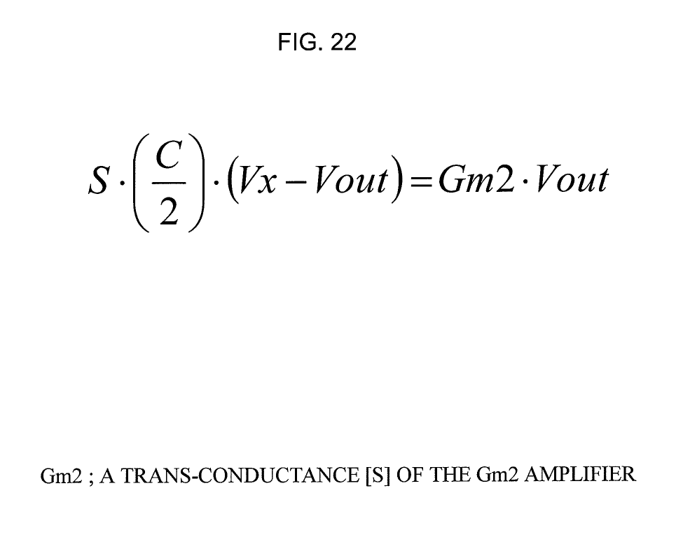

The buffer circuit 5b of FIG. 21 realizes 1/Gm2 as a signal source impedance viewed from an HPF stage, and the amplifier circuit 4b realizes a double gain. Assuming that a voltage Vx is applied to the output end of the buffer circuit 5b of FIG. 21, the relational expression of FIG. 22 is established regarding a current charged to C/2.

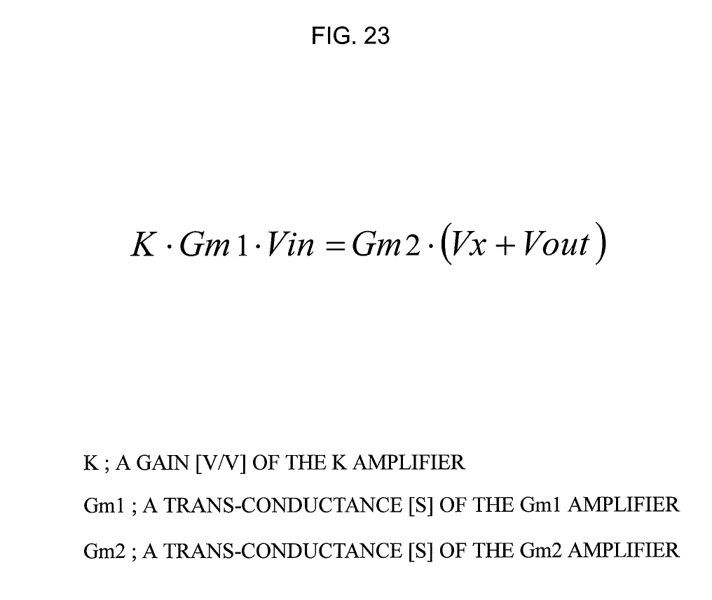

Further, the relational expression of FIG. 23 is established by Kirchhoff's first law (Kirchhoff's current law).

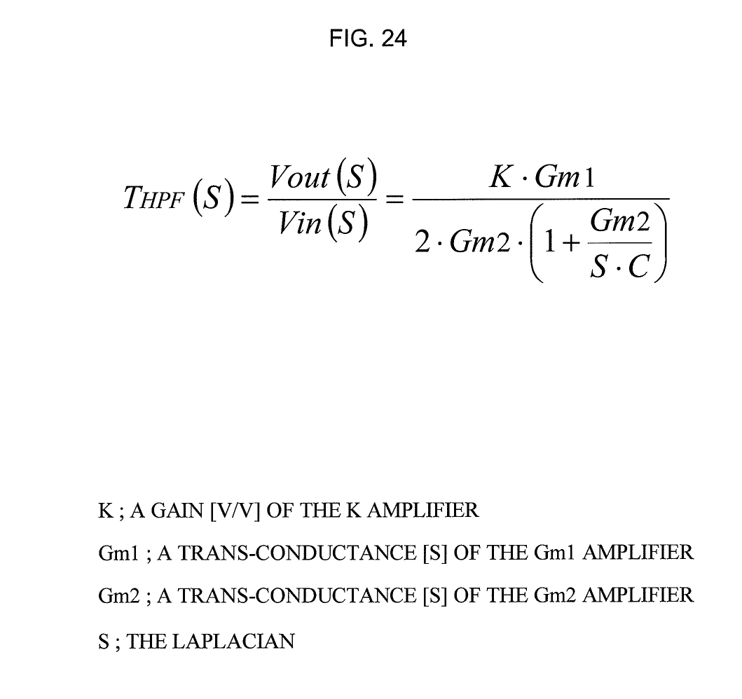

When removing Vx from the two expressions of FIGS. 22 and 23, a transfer function THPF(S) of the HPF stage is determined as shown in FIG. 24.

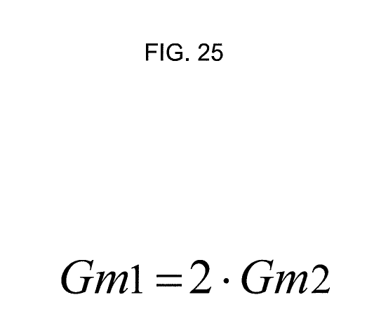

In order to obtain a double gain, the conditions of the expressions of FIG. 25 are provided between Gm1 and Gm2 in a compensation circuit.

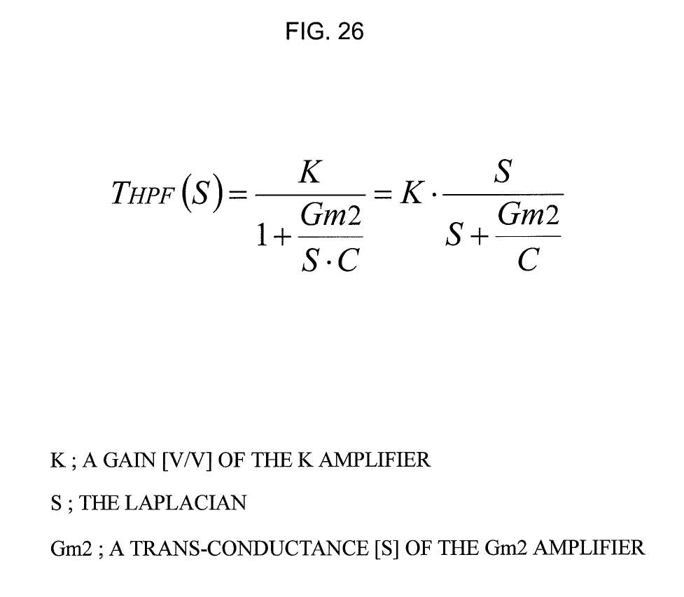

Considering the above relational expressions, the final transfer function of the HPF stage after compensation is obtained as shown in FIG. 26. The final transfer function is the same as the original transfer function having an ignored signal source impedance.

Since Gm1 is a high-input impedance, in this case, the output impedance of a K amplifier may be ignored. The compensation circuit of the present embodiment can be effective when an input impedance has a low load. Further, each Gm circuit can be adjusted by a current or a voltage. By adjusting each Gm to a constant and proper value in response to environmental variations and variations in manufacturing, stable characteristics can be kept.

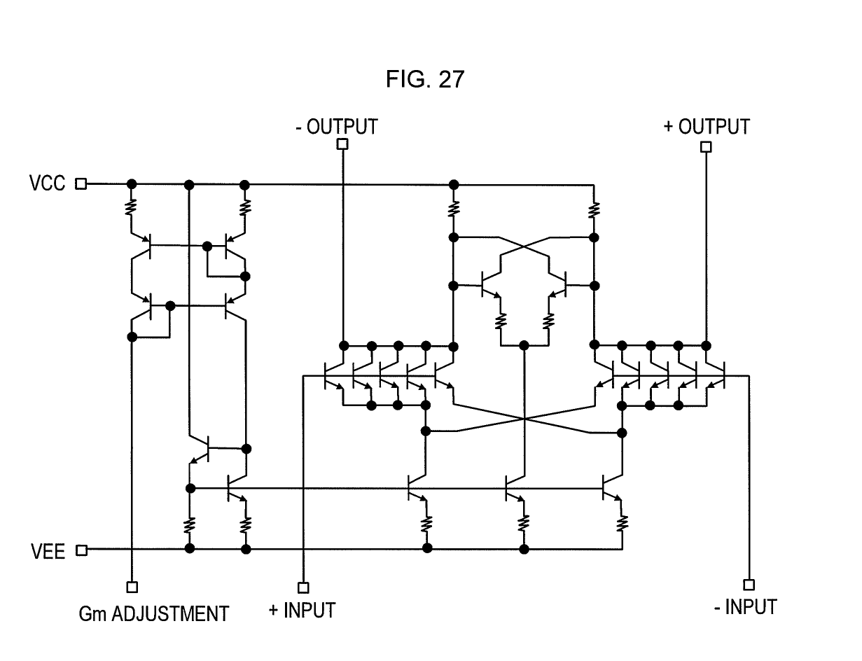

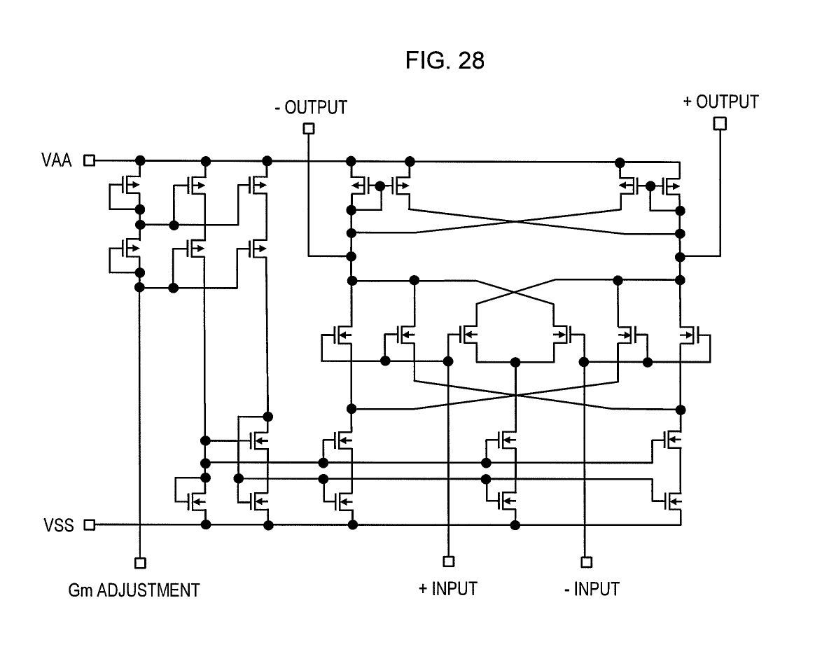

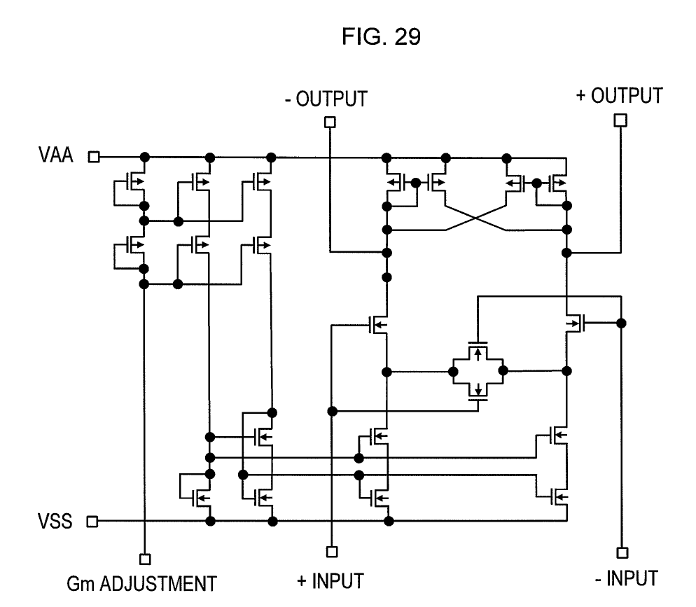

A voltage-current conversion circuit used for the resistor circuit 2b, the buffer circuit 5b, and the amplifier circuit 4b will be described below. The following will discuss three examples of the voltage-current conversion circuit using a transistor. FIG. 27 is a circuit diagram showing an example of the configuration of a voltage-current conversion circuit having a bipolar unbalanced differential pair. FIG. 28 is a circuit diagram showing an example of the configuration of a voltage-current conversion circuit having a CMOS unbalanced differential pair. FIG. 29 is a circuit diagram showing an example of the configuration of a voltage-current conversion circuit having a CMOS linear resistor.

According to the present embodiment, the buffer circuit having the same output impedance as the resistor circuit is inserted between the signal source and C in the fully differential primary HPF using C in a floating state, so that the influence of the signal source impedance on frequency characteristics can be offset and a difference between a design value and actual characteristics can be reduced.

### 3. Third Embodiment

The present embodiment will describe a bilinear equalizer using the present technique.

A primary low pass filter (LPF) and a primary HPF are multiplied by a proper coefficient (amplification) and addition and subtraction are performed on the filters, so that various frequency characteristics can be obtained.

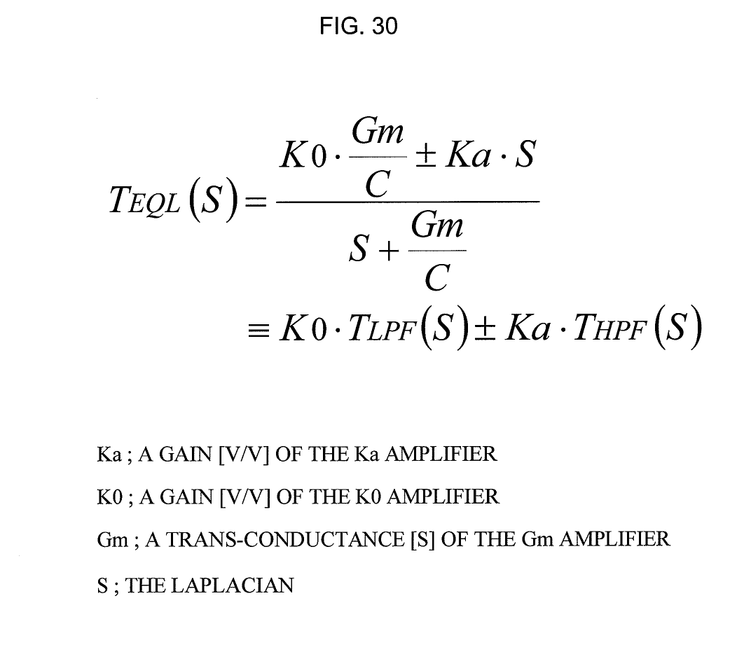

As an example, the following will examine a bilinear (1-pole/1-zero) equalizer having a transfer function of TEQL(S) expressed in FIG. 30.

In the case of K0>Ka, TEQL(S) is a low-frequency emphasis (high-frequency suppression) transfer function. In the case of Ka>K0, TEQL(S) is a high-frequency emphasis (low-frequency suppression) transfer function. The high-frequency emphasis transfer function can be used for compensating for a band and the like of a transmission line (for high-frequency deterioration). When Ka has a negative sign (=−K0), TEQL(S) is an all-pass transfer function and only a phase changes with even amplitude characteristics.

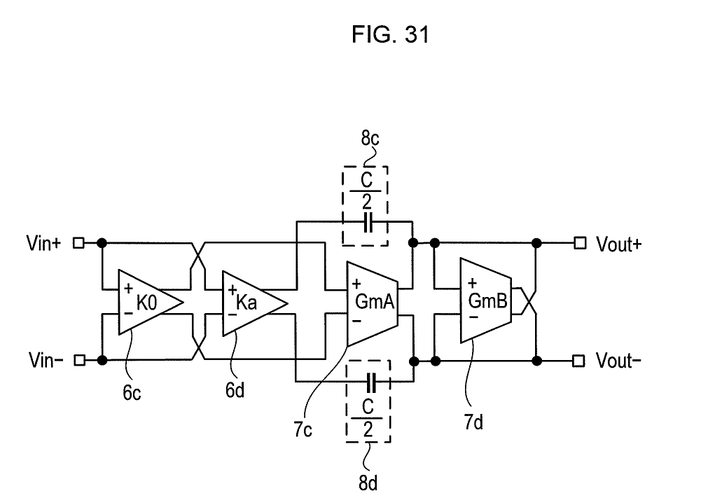

The following will describe the Gm-C configuration of the bilinear equalizer for realizing the transfer function TEQL(S). FIG. 31 is a circuit diagram showing an example of the configuration of the bilinear equalizer. The bilinear equalizer includes a K0 amplifier 6c, a Ka amplifier 6d, voltage-current conversion circuits 7c and 7d, and two capacitors 8c, 8d. An input Vin is inputted to the K0 amplifier 6c and the Ka amplifier 6d. The voltage-current conversion circuit 7c is connected downstream of the K0 amplifier 6c. The capacitors 8c, 8d in a floating state are connected downstream of the Ka amplifier 6d. The voltage-current conversion circuit 7d is connected downstream of the voltage-current conversion circuit 7c and the capacitors 8c, 8d, and the output of the voltage-current conversion circuit 7d is provided as negative feedback. The capacitors 8c, 8d each have a capacitance of C/2. The voltage-current conversion circuits 7c and 7d have conductances of GmA and GmB, respectively.

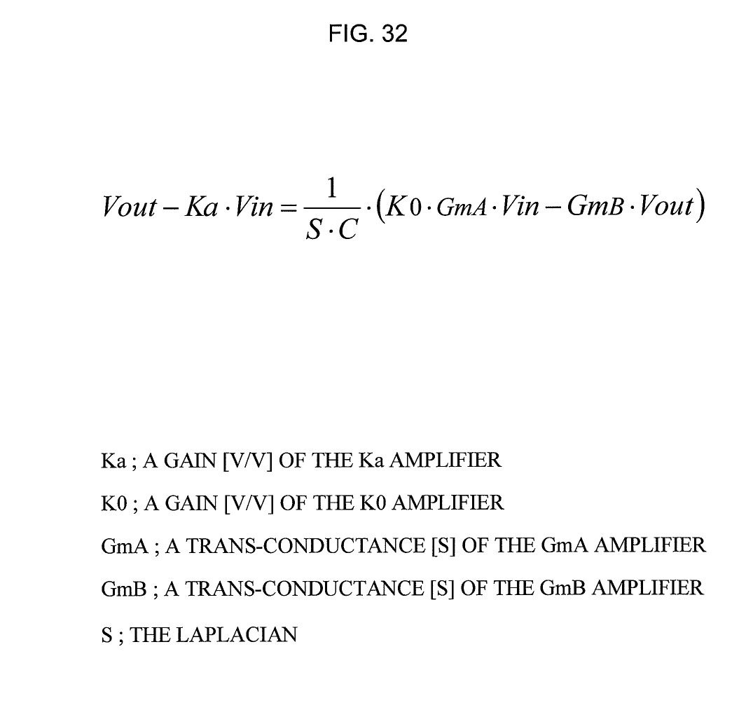

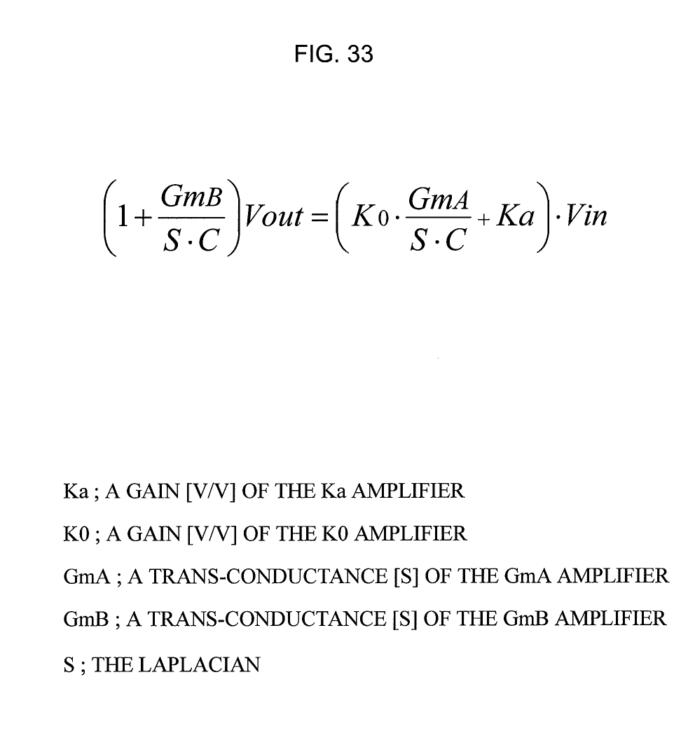

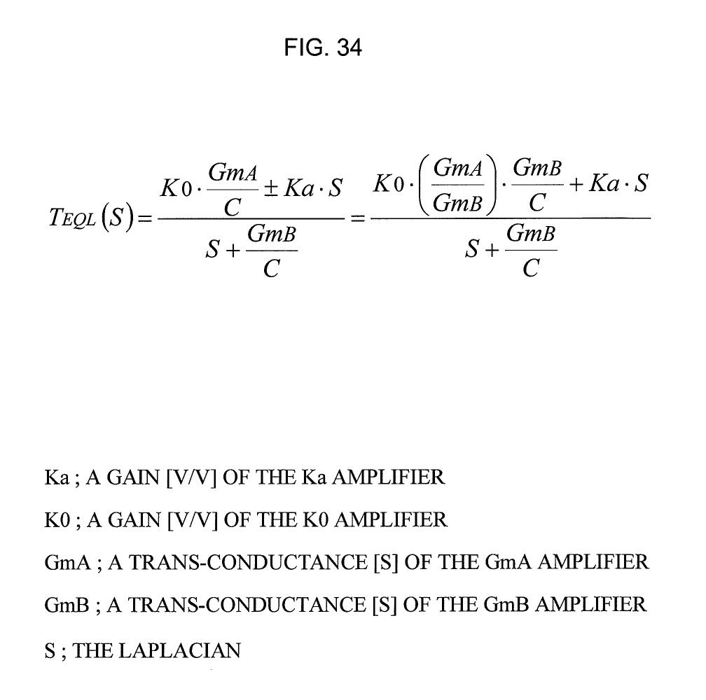

Regarding a charge accumulated in C in this bilinear equalizer, the relational expression of FIG. 32 is established. From the expression of FIG. 32, the expression of FIG. 33 is derived regarding Vout and Vin. Based on these two relational expressions, the transfer function TEQL(S) of the bilinear equalizer is expressed as shown in FIG. 34.

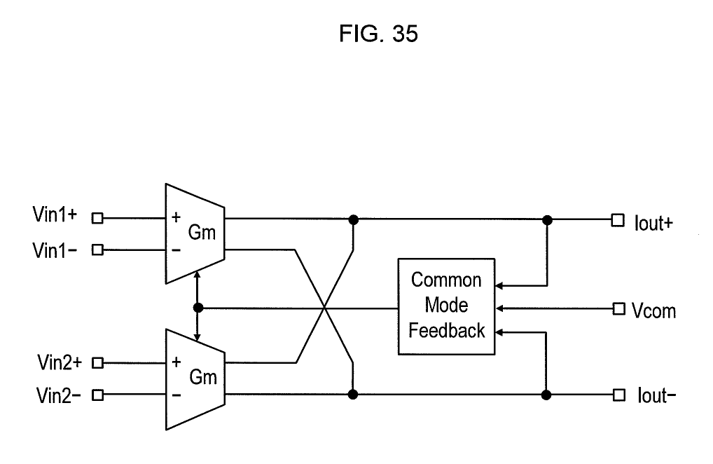

As is evident from this expression, the relative ratio of GmA and GmB is a factor of the gain variations of low-pass components. Thus GmA and GmB have to be produced in similar circuits with high accuracy. A pair of GmA and GmB has common outputs and thus is desirably designed as a Gm stage of dual-input type sharing a common-mode feedback loop. FIG. 35 is a circuit diagram showing an example of the Gm stage of dual-input type sharing the common-mode feedback loop.

The following will describe the influence of the output impedance of the variable amplifier in the bilinear equalizer.

The first and second embodiments described the influence of the output impedance of the signal source and the means of offsetting the influence in the primary HPF. The following will analyze, by similar analogy, the influence of a signal source impedance in the bilinear equalizer using the same floating C.

In the bilinear equalizer, the output impedance of the variable amplifier Ka is significant, which is the input of the floating C. The load of the variable amplifier K0 is not considered because the load is on the Gm stage having a high input impedance. Further, regarding the input signal source of the overall equalizer, a load viewed from the signal source is obtained from the variable amplifiers K0 and Ka and thus a sufficiently high input impedance does not cause a serious problem.

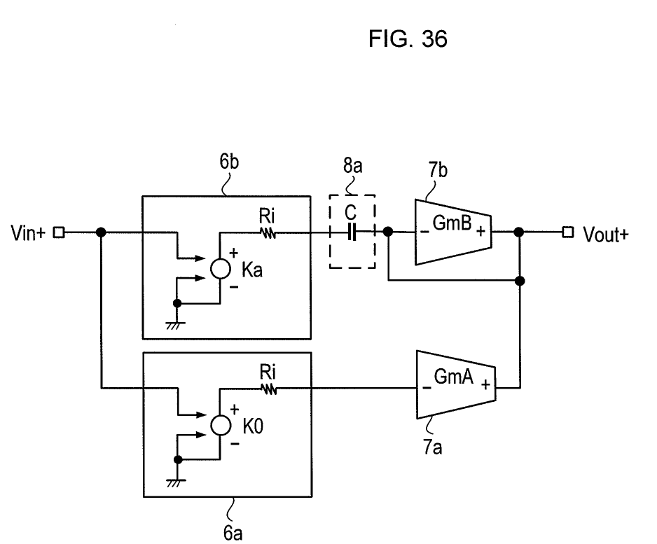

FIG. 36 is a circuit diagram of an equivalent circuit illustrating an example of the configuration of a bilinear equalizer in consideration of an output impedance Ri of a variable amplifier Ka. The bilinear equalizer includes a K0 amplifier 6a, a Ka amplifier 6b, voltage-current conversion circuits 7a and 7b, and a capacitor 8a. An input Vin is inputted to the K0 amplifier 6a and the Ka amplifier 6b. The voltage-current conversion circuit 7a is connected downstream of the K0 amplifier 6a. The capacitor 8a in a floating state is connected downstream of the Ka amplifier 6b. The voltage-current conversion circuit 7b is connected downstream of the voltage-current conversion circuit 7a and the capacitor 8a and the output of the voltage-current conversion circuit 7b is provided as negative feedback. The capacitor 8c has a capacitance of C. The voltage-current conversion circuits 7a and 7b have conductances of GmA and GmA, respectively. For simplicity, the output impedances Ri of the K0 amplifier 6a and the Ka amplifier 6b are represented as pure resistances.

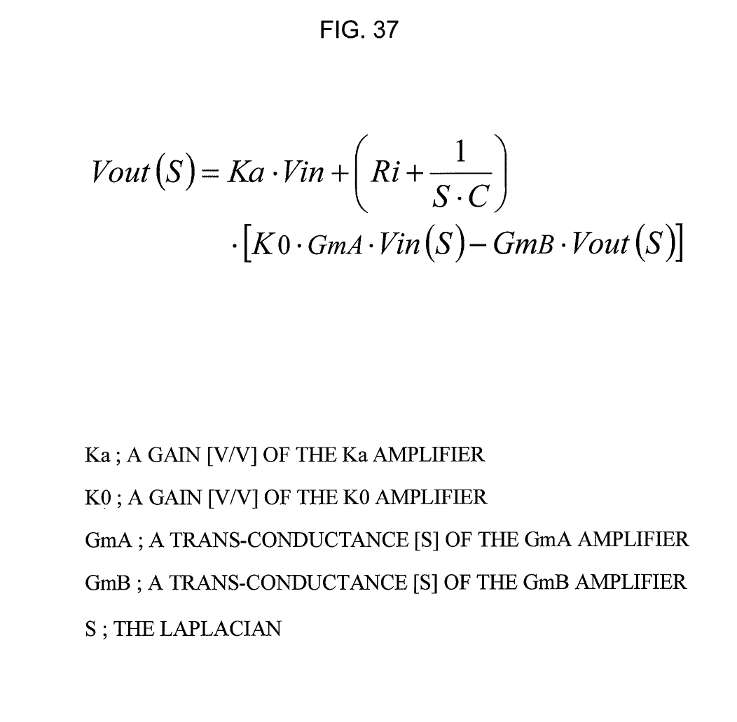

Regarding an output Vout of the equalizer, the relational expression of FIG. 37 is established.

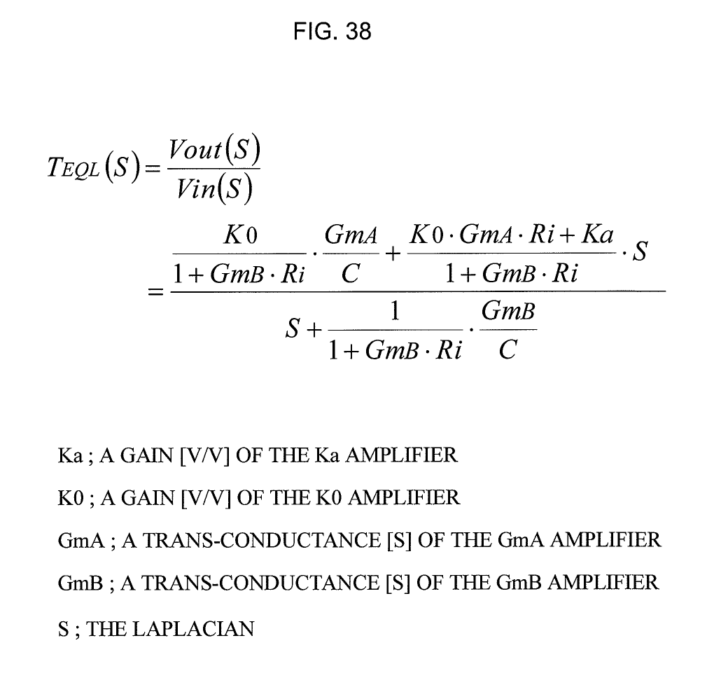

Based on this expression, a transfer function TEQL(S) is expressed as shown in FIG. 38.

As is evident from this expression, as in the primary HPF, the presence of Ri reduces a cutoff frequency and a gain to 1/(1+Gm·Ri). Since a gain parameter K0 of an LPF component relates to the gain of an HPF component, the transfer function of the equalizer is slightly more complicated than the transfer function of the primary HPF. In this case, GmA and GmB are uniformly made in similar circuit cells. In order to bring the transfer function close to the original transfer function, the output impedance Ri of Ka is changed to 1/Gm and C is reduced to a half as in the primary HPF.

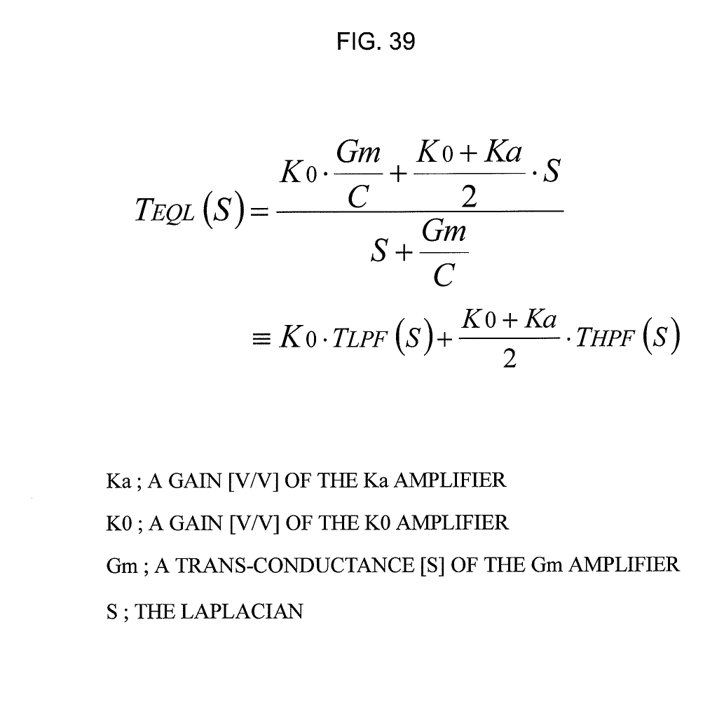

As a result of the compensation, a new transfer function TEQL(S) of the equalizer is expressed as shown in FIG. 39.

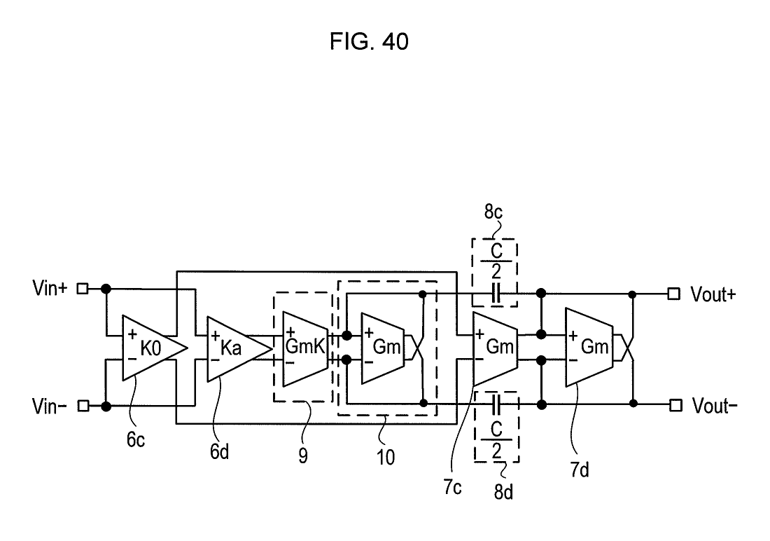

It should be noted that the gain setting of the HPF component is given as (K0+K2)/2. The following will describe the configuration of the Gm-C circuit of a bilinear equalizer having been corrected in consideration of the output impedance of a variable amplifier stage Ka. FIG. 40 is a circuit diagram showing an example of the configuration of a bilinear equalizer according to the third embodiment. In FIG. 40, the same reference numerals as those of FIG. 31 denote components similar to or corresponding to the components of FIG. 31. As compared with FIG. 31, in FIG. 40, an amplifier circuit 9 is provided downstream of a Ka amplifier 6d and a buffer circuit 10 is provided downstream of the amplifier circuit 9. The amplifier circuit 9 is made up of a voltage-current conversion circuit having a conductance of GmK. The buffer circuit 10 is made up of a voltage-current conversion circuit having a conductance of Gm.

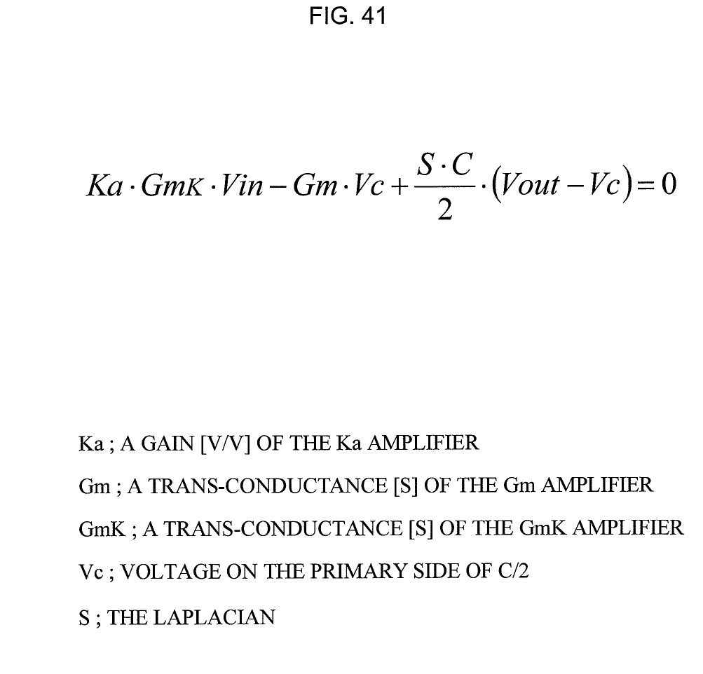

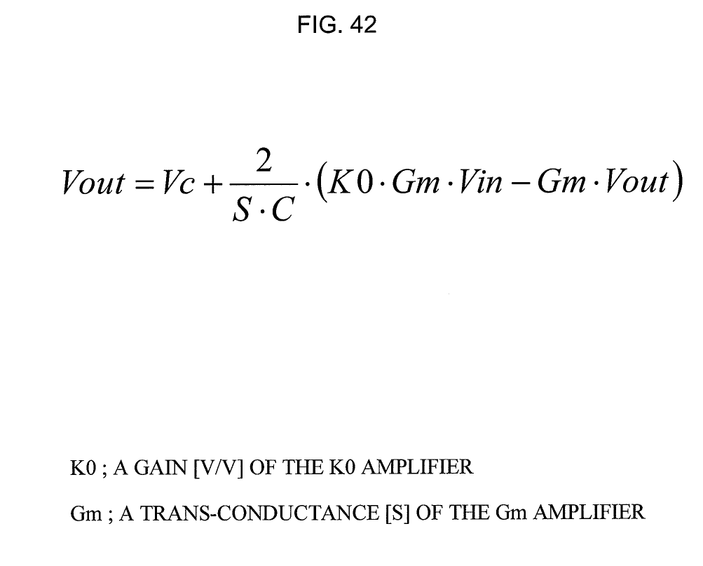

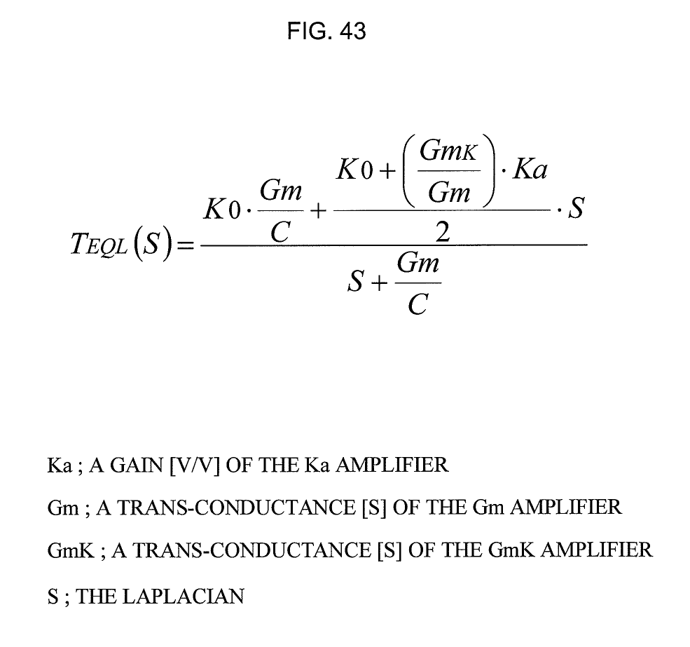

In this circuit, regarding a contact (Vc) on the primary side of C, the relational expression of FIG. 41 is established by Kirchhoff's first law (Kirchhoff's current law). Similarly, regarding an output Vout of the equalizer, the relational expression of FIG. 42 is established. Based on these two relational expressions, the transfer function of the equalizer is expressed as shown in FIG. 43.

In this case, coefficients (GmK/Gm) are given so as to compensate for a gain Ka. Since Gm is changed by a frequency, (GmK/Gm) is given as any fixed ratio and Gm and GmK are changed in synchronization with each other.

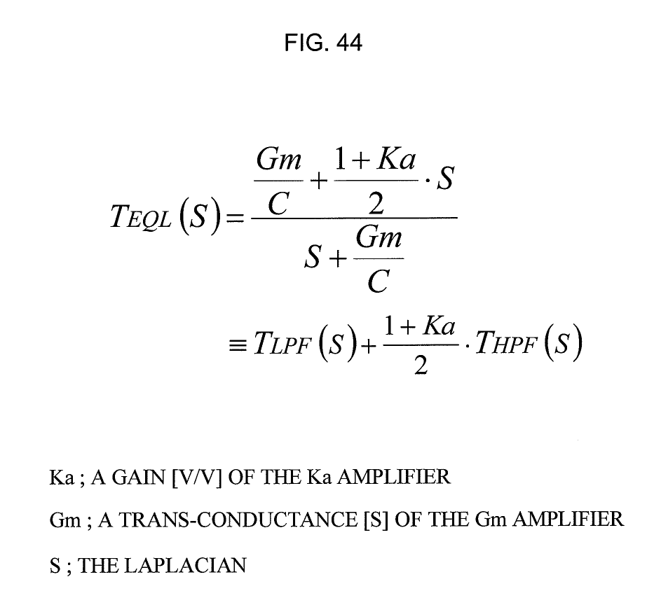

In a special case, under the conditions of GmK=Gm and K0=1 (reference level), the transfer function is given as a simplified high-frequency emphasis transfer function as expressed in FIG. 44.

In the case of Ka=1, the transfer function has even gain characteristics over all the frequency bands. In the case of Ka>1, the transfer function becomes a high-frequency emphasis transfer function.

The present embodiment can reduce the influence of a signal source impedance in the bilinear equalizer. Further, the bilinear equalizer can be used as a high-frequency emphasis circuit.

The filter circuit of the present technique is applicable to a data demodulation (reading) circuit in memory apparatus including a magnetic disk apparatus and an optical disk apparatus.

The following will describe a specific example in which the present technique is applied to a hard disk drive (HDD). The filter circuit of the present technique is disposed on the path of a Read signal read from a reading head. The Read signal in the HDD is transmitted from the reading head (slider) to a suspension, an actuator arm, and a preamplifier (a carriage assembly for loading the actuator arm or a fixed part such as a drive base) through a lead line or a flexible printed circuit (FPC) and the like, and then the Read signal is transmitted to a reproduced signal processing circuit (RDC: Read Channel) on a circuit board. In this configuration, the filter circuit of the present technique is mounted on the actuator arm or the fixed part and filters the Read signal.

By applying the filter circuit of the present technique to memory, the present technique can be sufficiently effective for a transfer rate which is expected to increase with recording density in the future. Further, by providing characteristics quite close to an ideal HPF, the present technique can be more effective as a frequency band increases.

The present technique can be practiced in various other forms without departing from the spirit or major characteristics thereof. Therefore, it is to be understood that the foregoing embodiments are merely illustrative in all respects and are not to limit the interpretation of the present technique. The scope of the present technique is to be made apparent by the accompanying claims but is not to be limited by the description of the specification. Also it is to be understood that all the variations, various improvements, substitutes, and modifications are all within the scope of the present technique.

The order in which the embodiments were described is not an indication of superiority of one embodiment over the other. Although the embodiments of the present inventions has been described in detail, it should be understood that the various changes, substitutions, and alterations could be made hereto without departing from the spirit and scope of the invention.

What is claimed is:

1. A filter circuit which can be connected to a signal source and has a low-frequency cutoff of 1/(R×C), comprising:
a buffer circuit which can be connected to an output end of the signal source and has an output impedance of R;
a capacitor which is connected to an output end of the buffer circuit in a floating state and has a capacitance of C/2; and
a resistor circuit which is connected to an output end of the capacitor and has a resistance value of R.

2. The filter circuit according to claim 1, wherein the resistor circuit is realized by providing negative feedback for a voltage-current conversion circuit having a conductance of 1/R, and
the buffer circuit is a circuit similar to the resistor circuit.

3. The filter circuit according to claim 1, further comprising an amplifier circuit disposed downstream of the signal source and upstream of the buffer circuit.

4. The filter circuit according to claim 3, wherein the resistor circuit is realized by providing negative feedback for a voltage-current conversion circuit having a conductance of 1/R,
the buffer circuit is a circuit similar to the resistor circuit, and
the amplifier circuit is a voltage-current conversion circuit having a conductance different from a conductance of the buffer circuit.

5. The filter circuit according to claim 3, wherein the amplifier circuit has a gain for compensating for attenuation of the buffer circuit.

6. The filter circuit according to claim 3, wherein the amplifier circuit has a double gain.

7. The filter circuit according to claim 3, wherein a voltage-current conversion circuit in the amplifier circuit has a conductance twice as high as a conductance of a voltage-current conversion circuit in the buffer circuit.

8. The filter circuit according to claim 1, wherein the buffer circuit, the capacitor, and the resistor circuit are fully differential.

9. The filter circuit according to claim 1, further comprising a low-pass circuit.

10. The filter circuit according to claim 9, wherein the low-pass circuit comprises a voltage-current conversion circuit.
